(19) United States
(12) Patent Application Publication
(10) Pub. No.: US 2024/0210466 A1
(43) Pub. Date: Jun. 27, 2024

(54) ENHANCED STATIC-DYNAMIC STRESS TECHNIQUES TO ACCELERATE LATENT DEFECTS FOR INTEGRATED CIRCUITS

(71) Applicant: Intel Corporation, Santa Clara, CA (US)

(72) Inventors: Andres MALDONADO, Beaverton, OR (US); Steve HERNDON, Chandler, AZ (US); Thomas POMPL, Landshut (DE)

(21) Appl. No.: 18/089,411

(22) Filed: Dec. 27, 2022

(51) Int. Cl. G01R 31/28; H01L 21/66

(52) U.S. Cl. CPC G01R 31/2879; G01R 31/2849; G01R 31/287; H01L 22/12

(57) ABSTRACT

This disclosure describes systems, methods, and devices related to testing an integrated circuit for defects. A method may include applying a nominal voltage to the integrated circuit for a first time period; applying a dynamic voltage greater than the nominal voltage to the integrated circuit for a second time period after the first time period; applying a static voltage greater than the dynamic voltage to the integrated circuit for a third time period after the second time period, wherein the static voltage is a target static voltage less than a target voltage; and applying the dynamic voltage to the integrated circuit during a fourth time period after the third time period.

### TECHNICAL FIELD

This disclosure generally relates to devices, systems, and methods for manufacturing integrated circuits and, more particularly, to prevent latent defects in integrated circuit manufacturing.

### BACKGROUND

To meet quality and reliability goals for integrated circuit manufacturing, stresses are applied during the manufacturing flow to prevent latent defects. The stresses include the execution of targeted tests at high-voltage to create high electric field and current densities across the design. However, ensuring both stress coverage and high-voltage can be challenging.

### BRIEF DESCRIPTION OF THE DRAWINGS

FIG. 1 illustrates a process for hybrid static-dynamic voltage stress application to an integrated circuit, in accordance with one or more example embodiments of the present disclosure.

FIG. 2A illustrates a process for dynamic voltage stress application to an integrated circuit, in accordance with one or more example embodiments of the present disclosure.

FIG. 2B illustrates a process for quasi-static voltage stress application to an integrated circuit, in accordance with one or more example embodiments of the present disclosure.

FIG. 3A is a graph showing the benefit of the hybrid static-dynamic voltage stress application of FIG. 1 compared to the dynamic voltage stress application of FIG. 2A and the quasi-static voltage stress application of FIG. 2B, in accordance with one or more example embodiments of the present disclosure.

FIG. 3B is a graph showing an example dynamic adjustment of voltage and stress applied to an integrated circuit, according to some example embodiments of the present disclosure.

FIG. 4 illustrates a flow diagram of an illustrative process for hybrid static-dynamic voltage stress application to an integrated circuit, in accordance with one or more example embodiments of the present disclosure.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

To meet quality and reliability goals in integrated circuit manufacturing, several stresses are applied during the manufacturing flow to prevent latent defects from reaching end customers. The stresses include the execution of targeted tests at high voltage with the goal to create high electric field and current densities across the design.

The specific operating conditions (e.g., voltage, temperature, time, etc.) for each stress are set by the manufacturing platform constraints and the defect reliability models. It is highly desirable to run stress at the highest possible voltage while using high-coverage tests that ensure that most of the silicon area is free from latent defects.

Ensuring both stress coverage and high voltage has become a compromise in the latest integrated circuit manufacturing process technologies. High-stress coverage requires determinism, which can only be guaranteed by proper timing closure at operating voltage. Timing closure at high voltage is being discouraged by some design teams because it translates into added design complexity and a significant area and performance impact as result of the logic added to mitigate hold-time violations. Furthermore, transistors models and library characterizations are not available at stress voltages, neither from the technology supplier nor from the provider. In many situations the timing closure at stress voltage is not performed, resulting in lower coverage or missing functionality during stress.

As an alternative to dynamic stress, different types of static and quasi-static stress are used. Although this strategy might be sufficient for mature process technologies with low defect density, it is increasingly risky and expensive for process technologies that are not fully mature. Static and quasi-static stress inherently have lower coverage and a higher manufacturing cost.

Existing solutions are summarized below in Table 1.

TABLE 1
Existing Solutions for High Stress Coverage in Integrated Circuit Manufacturing:

| Solution | Description | Advantages | Comments |
|---|---|---|---|
| Dynamic | Application of high | High stress coverage at | Requires timing- |
| Voltage Stress | coverage tests at | stress voltage | closure at stress voltage |
| | stress voltage | | |
| Static Stress | Static application of | High stress voltage is | Minimum possible |
| e.g., | stress voltage - No | possible due to no timing or | coverage |
| Enhanced | content execution | functionality requirements | |
| Voltage Stress | | | |
| Quasi-static | Alternate application | High stress voltage is | Low to medium |
| Voltage Stress | of stress voltage | possible due to no timing or | coverage, depending on |
| | interleaved with | functionality requirements | number of |
| | preconditioning | Higher coverage than Static | preconditioning cycles |
| | | Stress | Implementation time |
| | | | increases with number |
| | | | of precondition cycles |

The present disclosure enhances existing techniques by proposing a hybrid approach that combines dynamic and static stress. The enhancements presented herein allow for enabling dynamic stress for products where functionality is not met at stress voltage by combining bursts of dynamic stress interleaved with periods of static stress at high, the applied static stress acts like a quasi-static stress because each dynamic burst is a new preconditioning to the subsequent static stress. The enhancements presented herein combine the advantages of high coverage in the case of Dynamic Voltage Stress and high stress voltage in the case of Quasi-Static Voltage Stress. This allows for reducing test cost by saving stress time because the number of preconditioning of Quasi-static Voltage Stress can be reduced.

Traditional stress is applied by elevating the operating voltage of chip to a target voltage Vₛₜᵣₑₛₛ. This voltage is defined based on process technology characterization to ensure latent defects are accelerated properly to be screened by subsequent tests. The most common stress implementation is shown in the disclosure herein. After reset is complete, the power supply is elevated until the target voltage (Vₛₜᵣₑₛₛ) is reached. Logic or array content is executed during the stress duration tₛₜᵣₑₛₛ.

It is possible that the target voltage (Vₛₜᵣₑₛₛ) cannot be reached due to timing violations or dynamic power limitations. In those scenarios, the stress is applied statically at the target voltage and the logic or array under stress is randomized or preconditioned at nominal voltage. This implementation is shown in the disclosure herein. After the initial reset, logic or array content is executed set the target logic or array in a specific state. Once this is complete, the voltage is elevated and held high during tₛₜᵣₑₛₛ. This process is repeated multiple times setting the logic or array at different states to provide enough stress coverage. The time in stress is only determined by tₛₜᵣₑₛₛ (and the number of times the process of preconditioning the logic and rising the voltage is repeated).

The time spent preconditioning the logic (e.g., active toggling) does not contribute any value to the stress effectiveness because it is running at nominal voltage.

For static stress there is only one sequence of A followed by stress during idle. For increasing coverage, the quasi-static voltage stress executes many (e.g., >300) sequences of A followed by stress during idle.

In one or more embodiments, when Vₛₜᵣₑₛₛ cannot be reached, independently if it is driven by thermal or timing limitations, it may be possible to apply dynamic stress beyond nominal voltage up to a voltage called V_{dynamic}. If V_{dynamic} is close to the target Vₛₜᵣₑₛₛ, dynamic stress application contributes to the total latent defect acceleration on top of the static stress applied at the target Vₛₜᵣₑₛₛ voltage. The implementation is shown in the figure below. Static stress applied during t_{static} at target V_{static} voltage are interleaved with bursts of activity during t_{Dyn} applied at V_{Dynamic}. This is effectively interleaving low coverage/high voltage static stress with high coverage/low voltage dynamic stress. By gaining stress coverage due to dynamic stress, the hybrid approach herein allows for reducing the number of sequences of static stress during idle, which reduces stress time. The V_{dynamic} voltage may be less than the target voltage Vₛₜᵣₑₛₛ and greater than the nominal voltage, functioning as an intermediate voltage that accelerates some activity in the chip, even if less activity than when at the target voltage (e.g., 1.4 Volts versus 1.6 Volts). In this manner, rather than a fully static or fully dynamic process, the hybrid approach herein uses a combination of dynamic and static voltages.

Benefits of the enhanced approach herein include enhanced acceleration, cost optimization, and reduced burn-in time. Regarding enhanced acceleration, defect acceleration characteristics expressed in accumulative number of failures over time becomes a blend of static and dynamic elements. This could be advantageous compared to pure purely static or dynamic stress applications minimizing the penalty from not being able to run dynamic stress natively at target voltage. Regarding cost optimization, stress parameters like V_{dynamic} and t_{static} can be adjusted dynamically within a unit population based on power or other manufacturing constraints to optimize both cost and the benefit from hybrid stress. For example, low power units that can run dynamic stress at target voltage can set V_{static}=V_{dynamic} and t_{Static}=0 (e.g., converting the hybrid stress into dynamic stress). Some high power units can set V_{dynamic}=Vₙₒₘᵢₙₐₗ and maximize t_{Static} to provide maximum static stress. Implementing legacy dynamic stress or quasi-static stress does not provide the same flexibility. Regarding burn-in time, the enhancements herein have demonstrated a reduction from 9 hours to 24 minutes in some cases, while improving the stress application rate at the target voltage from 0% to over 99%. Further, switching between Vₛₜᵣₑₛₛ and V_{dynamic} provides the advantage of significantly less delta voltage and therefore, less time for voltage switching between dynamic and static stress. This allows reducing the time which means reducing test cost. Alternatively, within a specific targeted total time more states of preconditioning can be executed which increases test coverage.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

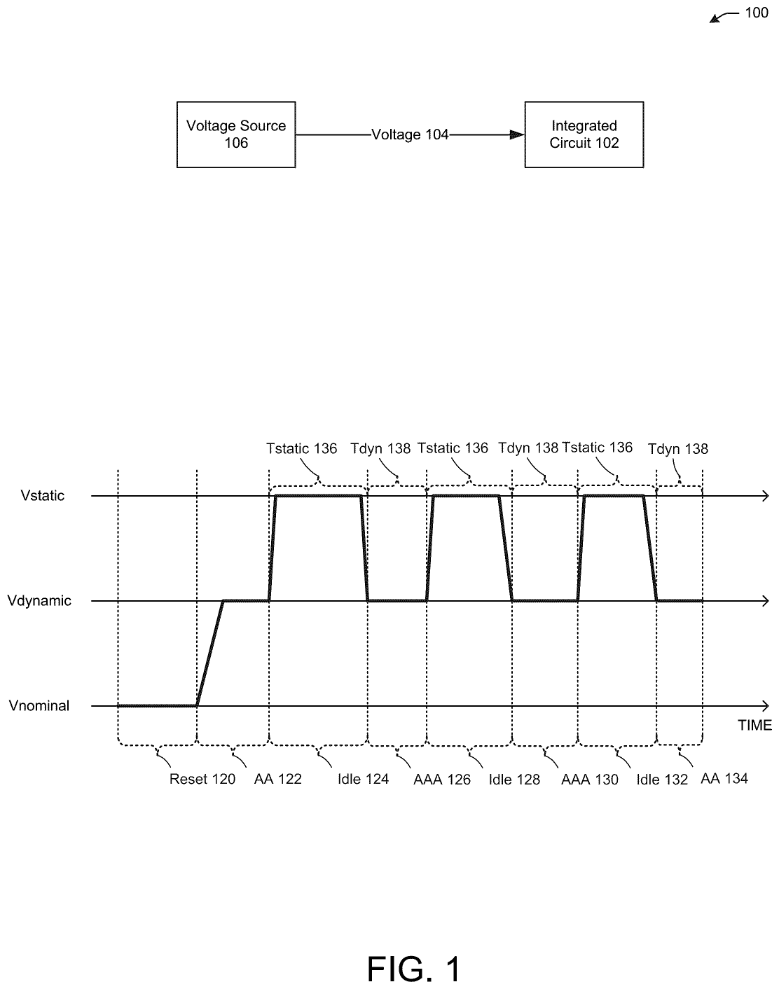

FIG. 1 illustrates a process 100 for hybrid static-dynamic voltage stress application to an integrated circuit, in accordance with one or more example embodiments of the present disclosure.

Referring to FIG. 1, an integrated circuit 102 may have a voltage 104 applied to it by a voltage source 106 over a time period including a reset time 120, an activity time (AA 122) representing a scan shift and/or array toggle time, an idle time 124 (e.g., static stress), an activity time (AAA 126) representing a scan shift and/or array toggle time, an idle time 128 (e.g., static stress), an activity time (AAA 130) representing a scan shift and/or array toggle time, an idle time 132 (e.g., static stress), and an activity time (AA 134) representing a scan shift and/or array toggle time. Each “A” may represent a scan shift or array toggle, so “AA” may refer to two such activity periods, and “AAA” may refer to three. Alternatively, each “A” may represent another type of integrated circuit testing period (e.g., not necessarily scan shift or array toggle, which are examples not meant to be limiting).

When Vₛₜᵣₑₛₛ cannot be reached, independently if it is driven by thermal or timing limitations, it may be possible for the voltage source 106 to apply dynamic stress to the integrated circuit 102 beyond nominal voltage up to a voltage called V_{dynamic}. If V_{dynamic} is close to the target Vₛₜᵣₑₛₛ, dynamic stress application contributes to the total latent defect acceleration on top of the static stress applied at the target Vₛₜᵣₑₛₛ voltage. The implementation is shown in FIG. 1. Static stresses applied during t_{Static} 136 at target V_{static} voltage is interleaved with bursts of activity during t_{Dyn} 138 applied at V_{Dynamic}. This is effectively interleaving low-coverage/high-voltage static stress with high-coverage/low-voltage dynamic stress. By gaining stress coverage due to dynamic stress, the hybrid approach allows for reducing the number of sequences of static stress during idle, which reduces stress time. For example, more idle time for the integrated circuit 102 during which static stress is applied increases the overall stress on the integrated circuit 102, and therefore the likelihood of a defect.

In one or more embodiments, the voltage source 106 may include a voltage regulator, electrodes, and/or the like. Testing the integrated circuit 102 for defects during or after application of the voltage 104 may use one of a number of techniques, including probing (e.g., electron beam probing, oscilloscopes, etc.).

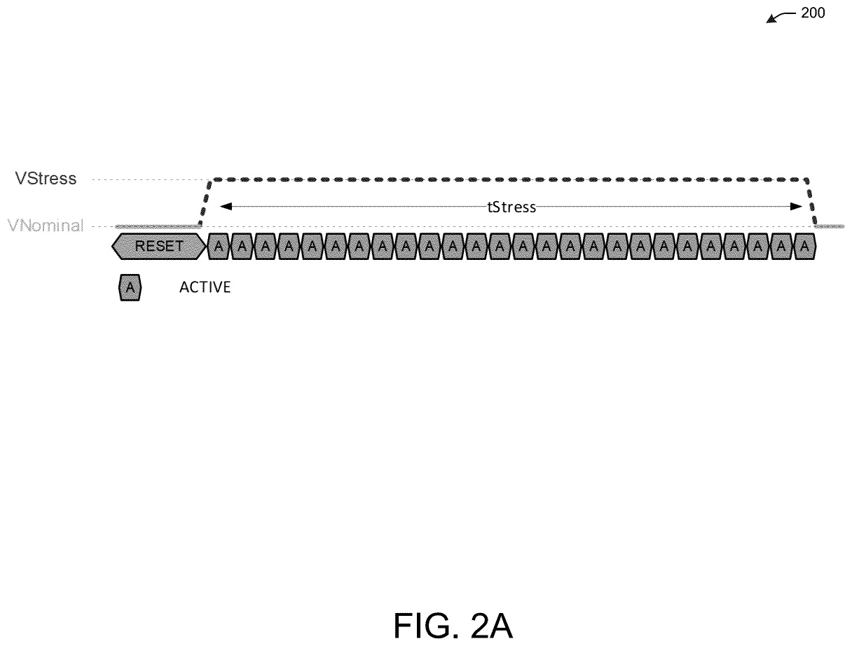

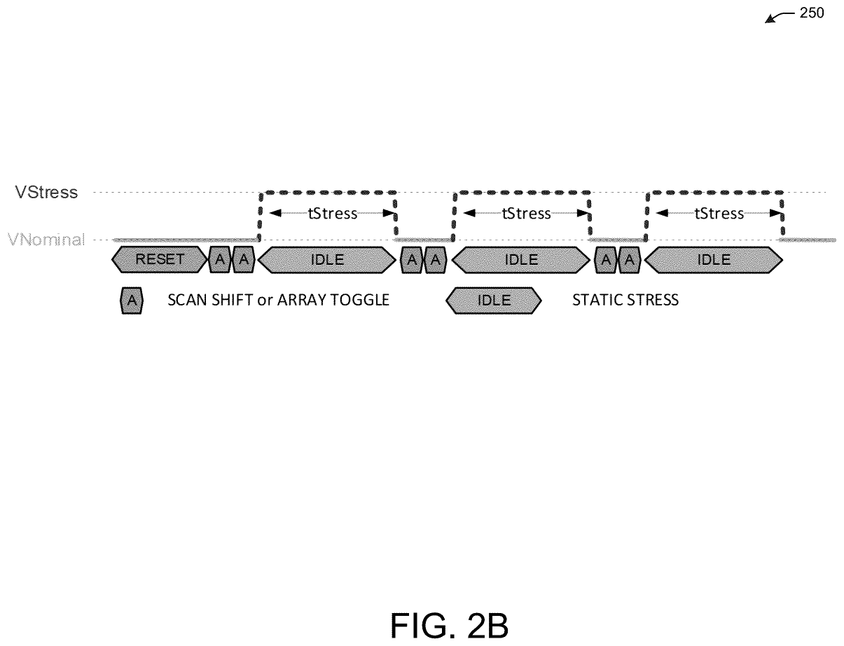

FIG. 2A illustrates a process 200 for dynamic voltage stress application to an integrated circuit, in accordance with one or more example embodiments of the present disclosure.

Referring to FIG. 2A, a nominal voltage Vₙₒₘᵢₙₐₗ may be applied to an integrated circuit (e.g., by the voltage source 106 to the integrated circuit 102 of FIG. 1) during a reset time, then during active times (e.g., represented by the respective “A” values), a dynamic voltage stress Vₛₜᵣₑₛₛ may be applied to the integrated circuit. The active time during which the Vₛₜᵣₑₛₛ is applied may be referred to as tₛₜᵣₑₛₛ.

Traditional stress is applied by elevating the operating voltage of the integrated circuit to a target voltage Vₛₜᵣₑₛₛ. This voltage is defined based on a process technology characterization to ensure latent defects are accelerated properly to be screened by subsequent tests. After reset is complete, the power supply is elevated until the target voltage (Vₛₜᵣₑₛₛ) is reached. Logic or Array content is executed during the stress duration tₛₜᵣₑₛₛ.

FIG. 2B illustrates a process 250 for quasi-static voltage stress application to an integrated circuit, in accordance with one or more example embodiments of the present disclosure.

Referring to FIG. 2B, it is possible that the target voltage (Vₛₜᵣₑₛₛ) cannot be reached due to timing violations or dynamic power limitations. In those scenarios the stress is applied statically at the target voltage, and the logic or array under stress is randomized or preconditioned at nominal voltage Vₙₒₘᵢₙₐₗ. After the initial reset, logic or array content is executed to set the target logic or array in a specific state. Once this is complete, the voltage is elevated and held high at Vₛₜᵣₑₛₛ during tₛₜᵣₑₛₛ (e.g., when idle). This process is repeated multiple times setting the logic or array at different states to provide enough stress coverage. The time in stress is determined by tₛₜᵣₑₛₛ (and the number of times the process of preconditioning the logic and rising the voltage is repeated). The time spent preconditioning the logic (active toggling) does not contribute any value to the stress effectiveness because it is running at nominal voltage. For Static Stress there is only one sequence of “A” followed by stress during idle. For increasing coverage, the Quasi-static Voltage Stress executes many (e.g., >300) sequences of A followed by stress during idle.

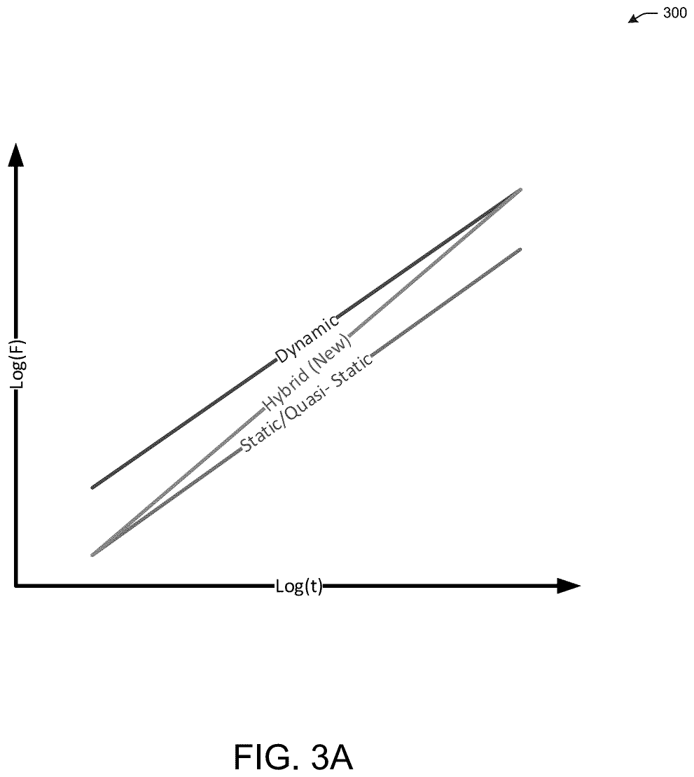

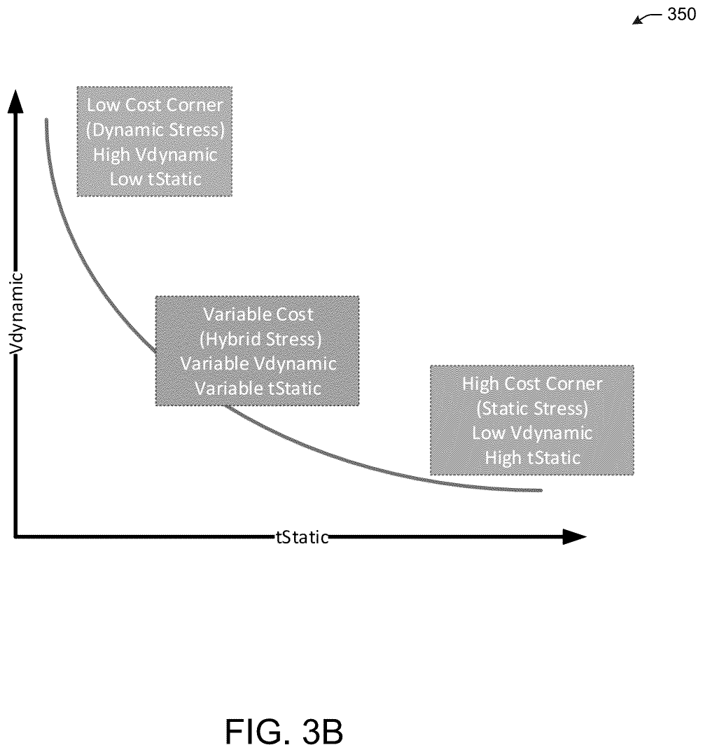

FIG. 3A is a graph 300 showing the benefit of the hybrid static-dynamic voltage stress application of FIG. 1 compared to the dynamic voltage stress application of FIG. 2A and the quasi-static voltage stress application of FIG. 2B, in accordance with one or more example embodiments of the present disclosure.

Referring to FIG. 3A, the “F” in the log(F) of the y-axis refers to fail rate. As shown in FIG. 3A, the fail rate of the hybrid static-dynamic voltage stress application of FIG. 1 remains between the fail rates of the dynamic voltage stress application of FIG. 2A and the quasi-static voltage stress application of FIG. 2B, respectively, over time.

FIG. 3B is a graph 350 showing an example dynamic adjustment of voltage and stress applied to an integrated circuit, according to some example embodiments of the present disclosure.

Referring to FIG. 3B, the graph 350 shows how the hybrid static-dynamic voltage stress application of FIG. 1 balances the amount of time during which the integrated circuit 102 of FIG. 1 may be under a high-voltage stress compared to the static and dynamic approaches.

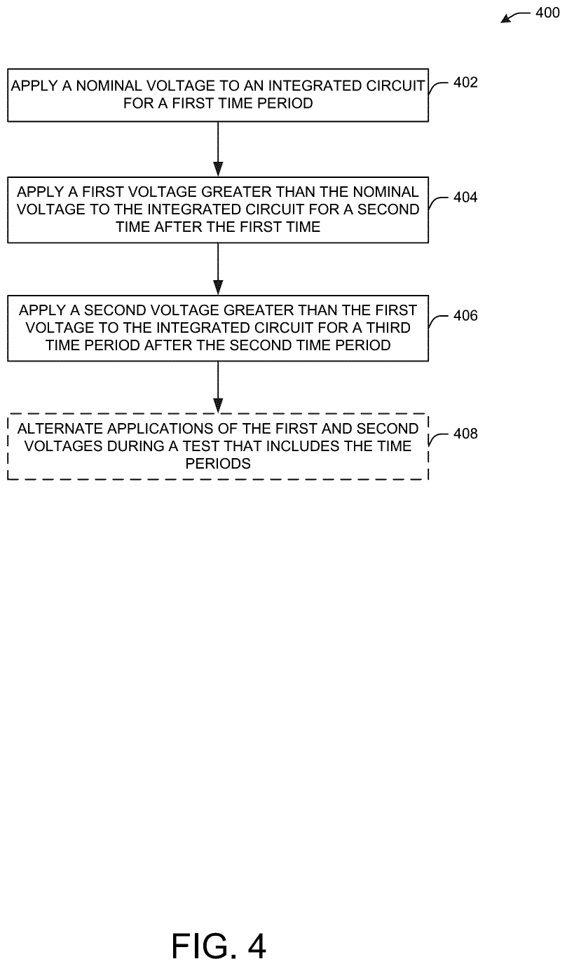

FIG. 4 illustrates a flow diagram of an illustrative process 400 for hybrid static-dynamic voltage stress application to an integrated circuit, in accordance with one or more example embodiments of the present disclosure. For example, the process 400 may represent at least portions of the hybrid process shown in FIG. 1.

At block 402, a device (e.g., the voltage source 106 of FIG. 1, or system including the voltage source 106 and the integrated circuit 102 of FIG. 1) may apply a nominal voltage to an integrated circuit under test during a first time period (e.g., a reset time).

At block 404 the device may apply a first voltage (e.g., a dynamic voltage) greater than the nominal voltage and less than a static voltage to the integrated circuit while testing the integrated circuit during a second time period after the first time period.

At block 406, the device may apply a second voltage (e.g., the static voltage) to the integrated circuit during a third time period after the second time period. The second voltage may be less than the target voltage at which to subject the integrated circuit to test for defects as a result.

At block 408, the device optionally may alternate between the first and second voltages for successive time periods (e.g., as shown in FIG. 1) to subject the integrated circuit to voltages above the nominal voltage while interleaving bursts of activity (e.g., scan shift and/or toggle array) with high-coverage/low-voltage dynamic stress for testing the integrated circuit for defects caused by the applied voltages.

It is understood that the above descriptions are for purposes of illustration and are not meant to be limiting.

As used in this application, the terms “system” and “component” and “module” are intended to refer to a computer-related entity, either hardware, a combination of hardware and software, software, or software in execution, examples of which are provided by the exemplary system 600. For example, a component can be, but is not limited to being, a process running on a processor, a processor, a hard disk drive, multiple storage drives (of optical and/or magnetic storage medium), an object, an executable, a thread of execution, a program, and/or a computer.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, yet still co-operate or interact with each other.

In addition, in the foregoing Detailed Description, various features are grouped together in a single example to streamline the disclosure. This method of disclosure is not to be interpreted as reflecting an intention that the claimed examples require more features than are expressly recited in each claim. Rather, as the following claims reflect, the inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

A data processing system suitable for storing and/or executing program code will include at least one processor coupled directly or indirectly to memory elements through a system bus. The memory elements can include local memory employed during actual execution of the program code, bulk storage, and cache memories that provide temporary storage of at least some program code to reduce the number of times code must be retrieved from bulk storage during execution. The term “code” covers a broad range of software components and constructs, including applications, drivers, processes, routines, methods, modules, firmware, microcode, and subprograms. Thus, the term “code” may be used to refer to any collection of instructions that, when executed by a processing system, perform a desired operation or operations.

Logic circuitry, devices, and interfaces herein described may perform functions implemented in hardware and implemented with code executed on one or more processors. Logic circuitry refers to the hardware or the hardware and code that implements one or more logical functions. Circuitry is hardware and may refer to one or more circuits. Each circuit may perform a particular function. A circuit of the circuitry may comprise discrete electrical components interconnected with one or more conductors, an integrated circuit, a chip package, a chipset, memory, or the like. Integrated circuits include circuits created on a substrate such as a silicon wafer and may comprise components. Integrated circuits, processor packages, chip packages, and chipsets may comprise one or more processors.

Processors may receive signals such as instructions and/or data at the input(s) and process the signals to generate at least one output. While executing code, the code changes the physical states and characteristics of transistors that make up a processor pipeline. The physical states of the transistors translate into logical bits of ones and zeros stored in registers within the processor. The processor can transfer the physical states of the transistors into registers and transfer the physical states of the transistors to another storage medium.

A processor may comprise circuits to perform one or more sub-functions implemented to perform the overall function of the processor. One example of a processor is a state machine or an application-specific integrated circuit (ASIC) that includes at least one input and at least one output. A state machine may manipulate the at least one input to generate the at least one output by performing a predetermined series of serial and/or parallel manipulations or transformations on the at least one input.

The logic as described above may be part of the design for an integrated circuit chip. The chip design is created in a graphical computer programming language, and stored in a computer storage medium or data storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication.

The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a processor board, a server platform, or a motherboard, or (b) an end product.

The word “exemplary” is used herein to mean “serving as an example, instance, or illustration.” Any embodiment described herein as “exemplary” is not necessarily to be construed as preferred or advantageous over other embodiments.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

The following examples pertain to further embodiments.

Example 1 may include a method for testing an integrated circuit for defects, the method comprising: applying a nominal voltage to the integrated circuit for a first time period; applying a dynamic voltage greater than the nominal voltage to the integrated circuit for a second time period after the first time period; applying a static voltage greater than the dynamic voltage to the integrated circuit for a third time period after the second time period, wherein the static voltage is a target static voltage less than a target voltage; and applying the dynamic voltage to the integrated circuit during a fourth time period after the third time period.

Example 2 may include the method of example 1 and/or any other example herein, wherein the second time period and the fourth time period are activity time periods.

Example 3 may include the method of example 2 and/or any other example herein, wherein performance of at least one integrated circuit test occurs during the activity time periods.

Example 4 may include the method of example 1 and/or any other example herein, wherein the third time period is an idle time period.

Example 5 may include the method of example 1 and/or any other example herein, wherein the target voltage is not applied to the integrated circuit during a test for defects of the integrated circuit.

Example 6 may include the method of example 1 and/or any other example herein, wherein the first time period, the second time period, the third time period, and the fourth time period are contiguous time periods.

Example 7 may include the method of example 1 and/or any other example herein, further comprising: applying the static voltage to the integrated circuit during a fifth time period after the fourth time period.

Example 8 may include the method of example 1 and/or any other example herein, wherein the second time period and the fourth time period are different in duration.

Example 9 may include a device for testing an integrated circuit for defects, the device comprising a voltage source configured to: apply a nominal voltage to the integrated circuit for a first time period; apply a dynamic voltage greater than the nominal voltage to the integrated circuit for a second time period after the first time period; apply a static voltage greater than the dynamic voltage to the integrated circuit for a third time period after the second time period, wherein the static voltage is a target static voltage less than a target voltage; and apply the dynamic voltage to the integrated circuit during a fourth time period after the third time period.

Example 10 may include the device of example 9 and/or any other example herein, wherein the second time period and the fourth time period are activity time periods.

Example 11 may include the device of example 10 and/or any other example herein, wherein performance of at least one integrated circuit test occurs during the activity time periods.

Example 12 may include the device of example 9 and/or any other example herein, wherein the third time period is an idle time period.

Example 13 may include the device of example 9 and/or any other example herein, wherein the target voltage is not applied to the integrated circuit during a test for defects of the integrated circuit.

Example 14 may include the device of example 9 and/or any other example herein, wherein the first time period, the second time period, the third time period, and the fourth time period are contiguous time periods.

Example 15 may include the device of example 9 and/or any other example herein, wherein the voltage source is further configured to: apply the static voltage to the integrated circuit during a fifth time period after the fourth time period.

Example 16 may include the device of example 9 and/or any other example herein, wherein the second time period and the fourth time period are different in duration.

Example 17 may include a system for testing an integrated circuit for defects, the system comprising: the integrated circuit; and a voltage source configured to: apply a nominal voltage to the integrated circuit for a first time period; apply a dynamic voltage greater than the nominal voltage to the integrated circuit for a second time period after the first time period; apply a static voltage greater than the dynamic voltage to the integrated circuit for a third time period after the second time period, wherein the static voltage is a target static voltage less than a target voltage; and apply the dynamic voltage to the integrated circuit during a fourth time period after the third time period.

Example 18 may include the system of example 17 and/or any other example herein, wherein the second time period and the fourth time period are activity time periods.

Example 19 may include the system of example 18 and/or any other example herein, wherein performance of at least one integrated circuit test occurs during the activity time periods.

Example 20 may include the system of example 17 and/or any other example herein, wherein the third time period is an idle time period.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A method for testing an integrated circuit for defects, the method comprising:
applying a nominal voltage to the integrated circuit for a first time period;
applying a dynamic voltage greater than the nominal voltage to the integrated circuit for a second time period after the first time period;
applying a static voltage greater than the dynamic voltage to the integrated circuit for a third time period after the second time period, wherein the static voltage is a target static voltage less than a target voltage; and
applying the dynamic voltage to the integrated circuit during a fourth time period after the third time period.

2. The method of claim 1, wherein the second time period and the fourth time period are activity time periods.

3. The method of claim 2, wherein performance of at least one integrated circuit test occurs during the activity time periods.

4. The method of claim 1, wherein the third time period is an idle time period.

5. The method of claim 1, wherein the target voltage is not applied to the integrated circuit during a test for defects of the integrated circuit.

6. The method of claim 1, wherein the first time period, the second time period, the third time period, and the fourth time period are contiguous time periods.

7. The method of claim 1, further comprising:
applying the static voltage to the integrated circuit during a fifth time period after the fourth time period.

8. The method of claim 1, wherein the second time period and the fourth time period are different in duration.

9. A device for testing an integrated circuit for defects, the device comprising a voltage source configured to:
apply a nominal voltage to the integrated circuit for a first time period;
apply a dynamic voltage greater than the nominal voltage to the integrated circuit for a second time period after the first time period;
apply a static voltage greater than the dynamic voltage to the integrated circuit for a third time period after the second time period, wherein the static voltage is a target static voltage less than a target voltage; and
apply the dynamic voltage to the integrated circuit during a fourth time period after the third time period.

10. The device of claim 9, wherein the second time period and the fourth time period are activity time periods.

11. The device of claim 10, wherein performance of at least one integrated circuit test occurs during the activity time periods.

12. The device of claim 9, wherein the third time period is an idle time period.

13. The device of claim 9, wherein the target voltage is not applied to the integrated circuit during a test for defects of the integrated circuit.

14. The device of claim 9, wherein the first time period, the second time period, the third time period, and the fourth time period are contiguous time periods.

15. The device of claim 9, wherein the voltage source is further configured to:
apply the static voltage to the integrated circuit during a fifth time period after the fourth time period.

16. The device of claim 9, wherein the second time period and the fourth time period are different in duration.

17. A system for testing an integrated circuit for defects, the system comprising:
the integrated circuit; and
a voltage source configured to:
apply a nominal voltage to the integrated circuit for a first time period;
apply a dynamic voltage greater than the nominal voltage to the integrated circuit for a second time period after the first time period;
apply a static voltage greater than the dynamic voltage to the integrated circuit for a third time period after the second time period, wherein the static voltage is a target static voltage less than a target voltage; and
apply the dynamic voltage to the integrated circuit during a fourth time period after the third time period.

18. The system of claim 17, wherein the second time period and the fourth time period are activity time periods.

19. The system of claim 18, wherein performance of at least one integrated circuit test occurs during the activity time periods.

20. The system of claim 17, wherein the third time period is an idle time period.
